(19) United States
(12) Patent Application Publication
(10) Pub. No.: US 2010/0200283 A1
(43) Pub. Date: Aug. 12, 2010

(54) INSULATION PASTE FOR A METAL CORE SUBSTRATE AND ELECTRONIC DEVICE

(75) Inventors: Akira Inaba, Kawasaki-shi (JP); Masaki Hamaguchi, Kawasaki-shi (JP); Naoto Nakajima, Utsunomiya Tochigi (JP)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E. I. DU PONT DE NEMOURS AND COMPANY, Wilmington, DE (US)

(21) Appl. No.: 12/768,202

(22) Filed: Apr. 27, 2010

Related U.S. Application Data
(63) Continuation of application No. 11/820,986, filed on Jun. 20, 2007.

(51) Int. Cl. H05K 1/00; H05K 3/00

(52) U.S. Cl. 174/258; 427/97.4

(57) ABSTRACT

The insulation paste of the present invention contains (a) a glass powder, and (b) an organic solvent, wherein one or both of alumina (Al₂0₃) and titanium oxide (TiO₂) are contained in the paste as a glass diffusion inhibitor, and the content of this glass diffusion inhibitor is 12 to 50% by weight based on the content of inorganic component in the paste.

This application is a continuation of Ser. No. 11/820,986, filed on Jun. 20, 2007.

### BACKGROUND OF THE INVENTION

1. Field of the Invention

The present invention relates to an insulation paste for producing an insulation layer formed on a metal core substrate. In addition, the present invention relates to an electronic device produced using this insulation paste.

2. Technical Background

In recent years, metal core substrates have come to be frequently used as circuit substrates for various types of electronic and electrical devices and semiconductor devices. Metal core substrates have an electronic circuit formed on a plate-like metal base made of various types of metals or metal alloys such as copper, aluminum, iron, stainless steel, nickel or iron-nickel alloy with an insulation layer between the substrate and the electronic circuit. For example, a metal core substrate having an organic insulation layer is disclosed in Japanese Patent Application Laid-open No. H11-330309.

The electronic parts are mounted by solder on the above-mentioned substrates and it is necessary to reduce the contact resistance between the electronic circuit and the solder with a satisfactory connection.

In addition, positional accuracy of the electronic circuit on a metal core substrate is also required.

The insulation layer on a metal core substrate is provided (i) by organic materials such as epoxy with ceramic filler or (ii) by inorganic materials such as glass/ceramic through firing process.

It has been observed that there is a problem relating to increasing contact resistance between electronic circuits and solder on the insulation layer within a glass system. In the case of using a glass material for the insulation layer, the glass easily diffuses into the conductor film on the insulation layer when firing the conductor paste and the glass bleeds out onto the surface of the conductor film. This bleeding out increases the contact resistance between the conductor film and the solder on the insulation layer and decreases the adhesion strength between the both layers.

In addition, the insulation layer can re-flow during firing of a conductive layer. As a result of this re-flow, the conductor pattern moves from a target position.

It is desirable to improve the characteristics of fabricated electronic devices by preventing the diffusion of glass from an insulation layer to a conductor film during firing of a conductor paste.

### SUMMARY OF THE INVENTION

The present invention relates to an improved insulation paste for a metal core substrate that avoids the problem of diffusion of glass from an insulation layer to a conductor film during firing. The insulation paste of the present invention contains (a) a glass powder, and (b) an organic solvent, one or both of alumina (Al₂0₃) and titania (TiO₂) are contained in the paste as a glass diffusion inhibitor, and the content of this glass diffusion inhibitor is 12 to 50% by weight and preferably 12 to 30% by weight based on the content of inorganic component in the paste. The insulation paste of the present invention can contain the glass diffusion inhibitor as a component of the glass powder and/or as an additive, namely as a ceramic powder.

In the present invention, the glass powder preferably has a transition point of 320° C. to 480° C. and a softening point of 370° C. to 560° C.

The present invention further relates to an electronic device containing an insulation layer formed from the aforementioned insulation paste. This electronic device has a plate-like metal base, one or two or more insulation layers formed on the metal base, and an electronic circuit formed on the insulation layer, at least the insulation layer in contact with the electronic circuit contains one or both of alumina (Al₂O₃) and titania (TiO₂) as a glass diffusion inhibitor, and the content of the glass diffusion inhibitor is 12 to 50% by weight and preferably 12 to 30% by weight based on the content of inorganic component in the insulation layer.

In variations of the electronic device of the present invention, the insulation layer may be composed of two or more laminated insulation layers. In this case, only the insulation layer in contact with the electronic circuit may contain the glass diffusion inhibitor.

An electronic device produced using the insulation paste of the present invention has a satisfactory junction and low contact resistance between the conductor film and the solder.

In addition, in the case of using the insulation paste of the present invention, the movement of the conductor film (electronic circuit and the like) on the insulation layer from a target position during firing can be prevented.

### BRIEF DESCRIPTION OF THE DRAWINGS

FIG. 1 shows schematic drawings of an electronic device using a metal core substrate, with FIG. 1A showing an example of the case of a single insulation layer, and FIG. 1B showing an example of the case of multiple (2) insulation layers;

FIGS. 2A to 2E are drawings for explaining the production process of the electronic device of FIG. 1A;

FIG. 3 shows photographs of circuit substrates formed in Examples 1 to 7. (The photographs for the examples are labeled on these drawings as 3A-3G. The photographs for the Comparative Examples 1 to 4 are labeled 3H-3K.)

FIG. 4 shows electron micrographs of the surfaces of conductor films on circuit substrates formed in Examples 1 to 7 and Comparative Examples 1 to 4. (The micrographs for the examples 1-7 are labeled on these drawings as 4A-4G. The micrographs for the Comparative Examples 1 to 4 are labeled 4H-4K.)

### DETAILED DESCRIPTION OF THE INVENTION

The present invention is an insulation paste for a metal core substrate. The insulation paste of the present invention contains (a) a glass powder and (b) an organic solvent, and one or both of alumina (Al₂0₃) and titania (TiO₂) are contained in the paste as glass diffusion inhibitors.

In this manner, the insulation paste for a metal core substrate of the present invention contains Al₂O₃, TiO₂ or both in the insulation paste as a glass dispersion inhibitor. In the present description, a glass diffusion inhibitor refers to Al₂O₃, TiO₂ or both.

The insulation paste of the present invention can contain the glass dispersion inhibitor as a component of the glass powder, as a ceramic powder or as a ceramic powder and a component of the glass powder. In the present invention, Al₂O₃ and/or TiO₂ are contained as a component of the glass powder (the Al₂O₃ and/or TiO₂ are contained as a component of the network of glass structure.) or the Al₂O₃ and/or TiO₂ are added to the insulation paste as ceramic filler or powder separately from the glass powder (the Al₂O₃ and/or TiO₂ are not included as a component of the network of glass structure. The present invention also includes the case in which the Al₂O₃ and/or TiO₂ are contained as a component of the network of glass structure and ceramic filler and also as a ceramic filler.

As an example, the glass with Al₂O₃ and/or TiO₂ as network structure is prepared by mixing the metal oxide of silica, boron, bismuth and other metals with metal oxide or hydrate aluminum and titanium, followed by melting, quenching and culletizing. Next, this cullet is subjected to wet or dry mechanical crushing, followed by going through a drying step in the case of wet crushing, to obtain a powder. In the case of having a desired particle diameter, the classification of screening may be subsequently carried out as necessary.

The content of the Al₂O₃ and/or TiO₂ as glass diffusion inhibitor (s) is 12% to 50% by weight and preferably 12% to 30% by weight, based on the content of inorganic component in the insulation paste.

The ratio of the two components of Al₂O₃ and TiO₂ in the insulation paste in terms of the weight ratio thereof is Al₂O₃:TiO₂=100:0 to 0:100.

In the insulation paste for a metal core substrate of the present invention, the glass powder preferably has a transition point of 320° C. to 480° C. and a softening point of 370° C. to 560° C. The glass powder having such a transition point and softening point allows the fabrication of a metal core substrate having superior characteristics at firing temperatures of 650° C. or lower.

Although there are no particular limitations on the particle diameter and other properties of the glass powder, the glass powder preferably has a mean particle diameter (D50), for example, of 0.1 to 5 μm. If the mean particle diameter is less than 0.1 μm, paste dispersion becomes poor, while if the mean particle diameter exceeds 5 μm, defects such as voids and pinholes form after firing, thereby making it difficult to obtain a dense film.

The following provides an explanation of each component of the insulation paste for a metal core substrate of the present invention.

### 1. Glass Powder

Glass powders ordinarily used in insulation pastes for metal core substrates are the type of lead borosilicate glass or bismuth-zinc-silica-boron glass. Specific examples of which include glass disclosed in Japanese Patent Application Laid-open No. 2002-308645 (Bi₂O₃: 27 to 55%, ZnO: 28 to 55%, B₂O₃: 10 to 30%, SiO₂: 0 to 5%, Al₂O₃: 0 to 5%, La₂O₃: 0 to 5%, TiO₂: 0 to 5%, ZrO₂: 0 to 5%, SnO₂: 0 to 5%, CeO₂: 0 to 5%, MgO: 0 to 5%, CaO: 0 to 5%, SrO: 0 to 5%, BaO: 0 to 5%, Li₂O: 0 to 2%, Na₂O: 0 to 2%, K₂O: 0 to 2%), and glass disclosed in Japanese Patent Application Laid-open No. 2003-34550 (Bi₂O₃: 56 to 88%, B₂O₃: 5 to 30%, SnO₂+CeO₂: 0 to 5%, ZnO: 0 to 20%, SiO₂: 0 to 15%, Al₂O₃: 0 to 10%, TiO₂: 0 to 10%, ZrO₂: 0 to 5%, Li₂O: 0 to 8%, Na₂O: 0 to 8%, K₂O: 0 to 8%, MgO: 0 to 10%, CaO: 0 to 10%, SrO: 0 to 10%, BaO: 0 to 10%, CuO: 0 to 5%, V₂O₅: 0 to 5%, F: 0 to 5%).

### 2. Al₂O₃ and TiO₂ Powder

Although there are no particular limitations on the Al₂O₃ and TiO₂ powder able to be used in the insulation paste of the present invention, the mean particle diameter is preferably 0.1 to 5 μm for the same reasons as described for the glass powder.

### 3. Organic Solvent

The insulation paste of the present invention contains an organic solvent. There are no particular limitations on the type of organic solvent, and examples of organic solvents include α-terpineol, butyl carbitol, butyl carbitol acetate, decanol, octanol, 2-ethylhexanol and mineral spirits.

The organic solvent may also contain an organic binder and be in the form of a resin solution. Examples of organic binders include ethyl cellulose resin, hydroxypropyl cellulose resin, acrylic resin, polyester resin, polyvinyl butyral resin, polyvinyl alcohol resin, rosin-modified resin and epoxy resin.

Moreover, a dilution solvent may also be added to adjust viscosity. Examples of dilution solvents include terpineol and butyl carbitol acetate.

### 4. Additives

A thickener and/or stabilizer and/or other common additives (such as a sintering promoter) may or may not be added to the insulation paste of the present invention. Examples of other additives that can be added include dispersants and viscosity adjusters. The amount of additive is determined dependent on the characteristics ultimately required by the paste. The amount of additive can be suitably determined by a person with ordinary skill in the art. Furthermore, a plurality of types of additives may also be added.

The insulation paste of the present invention can be suitably produced with triple roll mill and the like

The present invention also includes an electronic device that uses the insulation paste for a metal core substrate described above.

The electronic device of the present invention is used in various applications in which circuit substrates and semiconductor substrates are applied, examples of which include, but are not limited to, power supply devices, hybrid IC, multi-chip modules (MCM) and bump grid arrays (BGA).

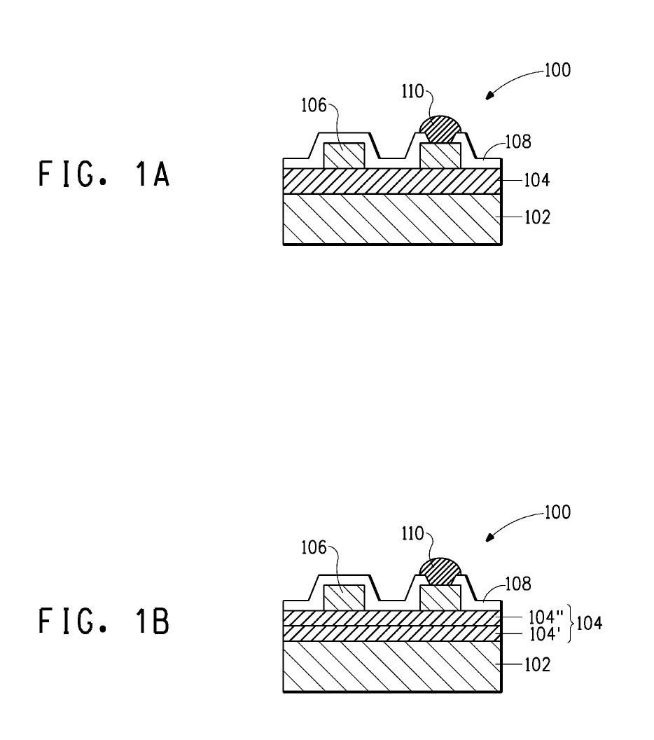

FIG. 1 schematically shows the constitution of an electronic device 100 using a metal core substrate. Reference symbol 102 indicates a plate-like metal base, 104 indicates an insulation layer, and 106 an electronic circuit. As shown in FIG. 1, the insulation layer 104 is provided on the plate-like metal base, and an electronic circuit is formed on this insulation layer. In addition, the electronic circuit 106 is covered by a protective film 108 in consideration of durability except for those portions connected to terminal portions such as electronic components, packaged components or modular components and the like with solder 110. There are no particular limitations on the thicknesses or other conditions of the insulation layer, electronic circuit and so on. These conditions may be within the range of conditions ordinarily used in electronic devices using metal core substrates.

The plate-like metal base 102 can be composed of a plate-like base made of various metals or alloys such as Cu, Al, Fe, stainless steel, Ni or FeNi. Various materials such as inorganic particles (such as SiC, Al₂O₃, AlN, BN, WC or SiN), inorganic fillers, ceramic particles or ceramic fillers may also be contained in these metals or alloys to improve the characteristics of the electronic device.

The plate-like base may also be in the form of a laminate composed of a plurality of materials.

The above-mentioned insulation paste for a metal core substrate of the present invention is used in the insulation layer 104.

In the electronic device of the present invention, the insulation layer 104 may be composed of a single layer (like that shown in FIG. 1A) or may be composed of multiple layers comprising two or more types of insulation paste (an example of two layers is shown in FIG. 1B). In the case the insulation layer is composed of multiple layers, the insulation paste for a metal core substrate of the present invention is required to be used in at least the uppermost layer 104″ (layer on which the electronic circuit is formed). Thus, in the present invention, in the case the insulating layer is composed of multiple layers, layers 104′ other than the uppermost layer (layer on which the electronic circuit is formed) can use the insulation paste for a metal core substrate of the present invention or another insulation paste.

A conductor paste is used in the electronic circuit 106. There are no particular limitations on the conductor paste provided it is used when forming a circuit on an insulation layer of a metal core substrate. For example, the conductor paste contains a conductive metal and a vehicle, as well as glass powder, inorganic oxide and the like as necessary. The glass powder, inorganic oxide and the like are contained at preferably 10% by weight or less, more preferably 0 to 5% by weight and even more preferably at 0 to 3% by weight to 100% by weight of the conductive metal.

The conductive metal is preferably gold, silver, copper, palladium, platinum, nickel, aluminum or an alloy thereof. The mean particle diameter of the conductive metal is preferably 8 μm or less.

Examples of glass powder include lead silicate glass, lead borosilicate glass and bismuth-zinc-silica-boron glass. In addition, examples of inorganic oxides include Al₂O₃, SiO₂, TiO₂, MnO, MgO, ZrO₂, CaO, BaO and CO₂O₃. Examples of vehicles include organic mixtures of binder resins (such as ethyl cellulose resin, acrylic resin, rosin-modified resin or polyvinyl butyral resin) and organic solvents (such as butyl carbitol acetate (BCA), terpineol, ester alcohol, BC or TPO).

The conductor paste is suitably produced by, for example, mixing each of the above components with a mixer and dispersing with a triple roll mill and the like.

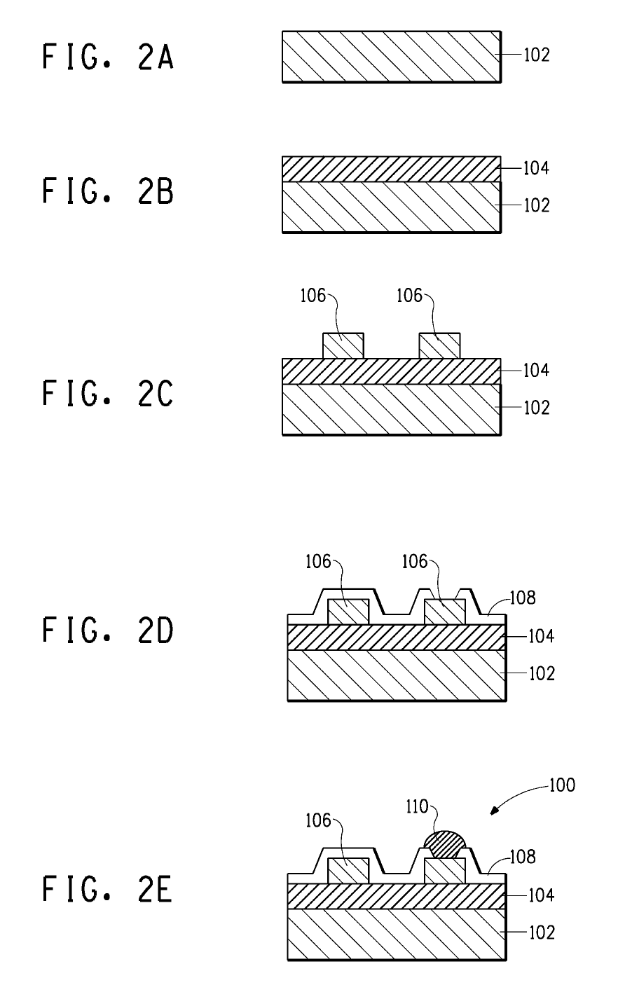

The electronic device of the present invention can be fabricated using a process, for example, as shown in FIG. 2. FIG. 2 is an example showing a production process of an electronic device containing a single layer of an insulation layer. First, a plate-like metal base 102 is prepared (FIG. 2A). The insulation paste for a metal core substrate of the present invention is then printed onto this plate-like metal base by, for example, screen printing followed by firing to obtain an insulation layer 104 (FIG. 2B). In the case of forming a plurality of insulation layers, this step is repeated for the desired number of layers. Next, a conductor paste for forming an electronic circuit 106 is printed in a desired pattern by screen printing and the like on the insulation layer followed by firing (FIG. 2C). Next, a protective film 108 is printed in a desired pattern by screen printing and the like (FIG. 2D). In this case, the protective film is printed so as to cover all components except for those portions connected with solder 110 to the terminal portions of electronic components, packaged components or modular components and the like. In the case of a protective film composed of glass or glass and ceramic, it is fired at a temperature equal to or lower than the firing temperature of the conductor paste. In the case of using an organic material such as an epoxy resin for the protective film, the protective film is formed by heat-curing at a temperature within the range of 100 to 200° C. Subsequently, solder paste is printed at those portions connected to the terminal portions of each component and after mounting those components at their predetermined locations, they are mounted by soldering in a solder reflow oven (FIG. 2E).

In the present invention, the insulation paste is used for a metal core substrate (or at least in the uppermost layer in the case where the insulation layer is composed of multiple layers). This leads to prevention of diffusion of glass from the insulation layer into the conductor film as occurred in the past that presented a problem when forming the insulating layer and an electronic circuit on a metal core substrate at a firing temperature of 650° C. or lower. As a result, the contact resistance between conductor and solder can be lowered, and a reliable electronic circuit can be formed on an insulation layer having solderability and accurate location of the electronic circuit.

### EXAMPLES

Although the following provides a detailed explanation of the present invention through examples thereof, these examples are only intended to be illustrative and do not limit the present invention.

### (A) Preparation of Insulation Pastes for Metal Core Substrate and Conductor Paste

Insulation pastes for a metal core substrate and a conductor paste were prepared according to the formulated amounts shown in Table 1.

TABLE 1

| | Total | | | | | Silver |
|---|---|---|---|---|---|---|
| | wt % of | Paste Sample No. | | | | Paste |
| | Al₂O₃ and | A | B | C | D | E |
| Material | TiO₂ | (wt %) | (wt %) | (wt %) | (wt %) | (wt %) |
| Glass A | 19.2 | 86 | — | — | — | — |
| Glass B | 14.3 | — | 79.4 | — | — | — |
| Glass C | 2.1 | — | — | 81.3 | — | — |
| Glass D | 0.5 | — | — | — | 81.3 | — |
| Silver | — | — | — | — | — | 86.3 |
| powder | | | | | | |
| Resin | — | 9.6 | 10.2 | 3.1 | 3.1 | 10.1 |
| solution | | | | | | |
| Dilution | — | 4.4 | 10.4 | 15.6 | 15.6 | 3.6 |
| solvent | | | | | | |

Each of the materials shown in the table were as described below.

Glass A: Glass (Bi₂O₃—SiO₂—B₂O₃-based glass) with Al₂O₃ as glass network composition was melted and quenched followed by the addition of TiO₂ ceramic filler thereto followed by mixing (Al₂O₃:TiO₂=4.8:14.4).

Glass B: Glass (Bi₂O₃—SiO₂—B₂O₃-based glass) with Al₂O₃ as glass network composition was melted and quenched followed by the addition of TiO ceramic filler thereto followed by mixing (Al₂O₃:TiO₂=3.0:11.3).

Glass C: Glass (Bi₂O₃—SiO₂—B₂O₃-based glass) with Al₂O₃ and TiO₂ as glass network composition (Al₂O₃:TiO₂=2.0:0.1) was melted and quenched.

Glass D: Glass (Bi₂O₃—SiO₂—B₂O₃-based glass) with Al₂O₃ as glass network composition (Al₂O₃=0.5) was melted and quenched.

Al₂O₃: Mean particle diameter: 0.4 to 0.6 μm

TiO₂: Mean particle diameter: 0.4 to 0.6 μm

Silver powder: Spherical powder having a mean particle diameter of 1.4 to 1.6 μm

Resin solution: Ethyl cellulose resin dissolved in terpineol (ethyl cellulose resin:terpineol=10:90 (wt/wt))

Dilution solvent: Terpineol or butyl carbitol acetate

Each component was weighed in a container according to the formulation of each paste followed by mixing with a mixer and dispersing with a triple roll mill.

### (B) Formation of Insulation Layer and Circuit on Metal Core Substrate

The insulation layer and silver conductor circuit were formed on metal core substrate. The process for forming the circuit substrates are as described below.

### Forming Process 1

### Examples 1, 2, 3, 4, 5 and Comparative Examples 1 and 2

A first insulation paste (bottom layer) was printed onto a stainless steel (SUS430) substrate (plate-like metal base) by screen printing to a thickness of 20 μm after firing. Next, the substrate was fired in the belt furnace at total 30 minutes profile with 10 minutes keep at 550° C. to obtain Insulation Layer 1. Then, a second insulation paste (top layer) was printed onto Insulation Layer 1 by screen printing under the same conditions as the first insulation paste followed by firing. As a result, Insulation Layer 2 was formed. Finally, a silver paste was printed onto the second insulation layer to a thickness of 15 μm after firing to form a silver conductor circuit by firing under the same conditions as the insulation pastes.

### Forming Process 2

### Examples 6, 7 and Comparative Examples 3 and 4

An insulation paste was printed onto a stainless steel (SUS430) substrate (plate-like metal base) by screen printing to a thickness after firing of 20 μm. The substrate was fired in the belt furnace at total 30 minutes profile with 10 minutes keep at 550° C. Next, a silver paste was printed onto the insulation layer to a thickness of 15 μm after firing followed by firing under the same conditions as the insulating paste to form a silver conductor circuit.

### (C) Evaluation

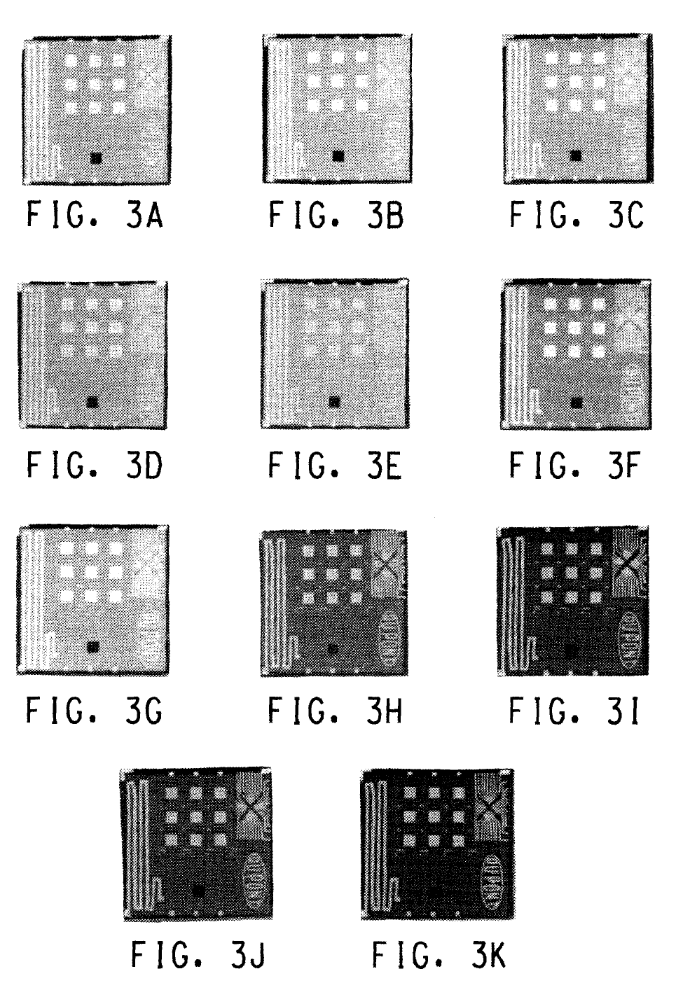

The circuit substrates of each of the examples and comparative examples were evaluated for (i) solderability on the silver conductor circuit, (ii) adhesive strength of the silver conductor circuit, and (iii) positional accuracy of the silver conductor circuit pattern. Each evaluation was carried out based on circuits formed in the patterns of the photographs shown in FIG. 3.

### (i) Solderability of Silver Conductor

The metal core substrates having insulation layers and silver conductor circuits prepared in each of the examples were soldered in lead-free solder composed of Sn, Ag and Cu at a ratio of 95.75/3.5/0.75 for 10 seconds at 240° C. Subsequently, the solderability on the conductor was observed. Those results are shown in Table 2. Furthermore, the evaluation specification are as described below.

Evaluation Specification:
OK: 95% or more of solder adhered to 2 mm² pattern of silver conductor surface
Marginal: 80% to less than 95% of solder adhered to 2 mm² pattern of silver conductor surface
NG: Less than 80% of solder adhered to 2 mm² pattern of silver conductor surface

### (ii) Silver Conductor Adhesive Strength

Tin-plated copper wire was attached to a 2 mm² silver conductor pattern using lead-free solder composed of Sn, Ag and Cu at a ratio of 95.75/3.5/0.75 followed by measuring the peeling strength of the copper wire perpendicular to the substrate with a tensile tester. Those results are shown in Table 2.

(iii) Positional Accuracy of Silver Conductor Pattern

The amount of shift from the predetermined position was observed for silver conductor circuit patterns measuring 0.5 mm (width)×100 mm (total length) (patterns on the left side when facing the page in FIG. 3) and fine silver conductor circuit patterns (upper right patterns when facing the page in FIG. 3) formed on an insulation layer. The absence of the occurrence of a positional shift was evaluated as OK, while the occurrence of a positional shift was evaluated as NG. Those results are shown in Table 2.

As is clear from the photographs in FIG. 3, in Examples 1 to 7 using the insulation paste for a metal core substrate of the present invention, there were no positional shifts in the circuit patterns (left side and upper right corner in the photographs). On the other hand, positional shifts occurred in the circuit patterns of Comparative Examples 1 to 4.

TABLE 2

| | Layer Structure | | | | Adhesive | |
|---|---|---|---|---|---|---|
| | Insulation | Insulation | Paste for | | strength after | |
| | paste of | paste of | silver | | soldering | Conductor |
| | Insulation | Insulation | conductor | Conductor | conductor (N: | pattern |
| Examples | Layer 1 | Layer 2 | circuit (Ag) | solderability | Mean) | position |
| Ex. 1 | A | A | E | OK | 17.1 | OK |
| Ex. 2 | B | B | E | OK | 15.2 | OK |
| Ex. 3 | A | B | E | OK | 18.9 | OK |
| Ex. 4 | C | B | E | Marginal | 8.0 | OK |
| Ex. 5 | D | B | E | Marginal | 7.8 | OK |
| Ex. 6 | A | — | E | OK | 16.4 | OK |
| Ex. 7 | B | — | E | OK | 14.4 | OK |
| Comp. 1 | C | C | E | NG | 0.0 | NG |
| Comp. 2 | D | D | E | NG | 0.0 | NG |
| Comp. 3 | C | — | E | NG | 0.0 | NG |
| Comp. 4 | D | — | E | NG | 0.0 | NG |

### (D) Results of Electron Microscopic Observation of Circuit Substrates of Examples 1 to 7 and Comparative Examples 1 to 4

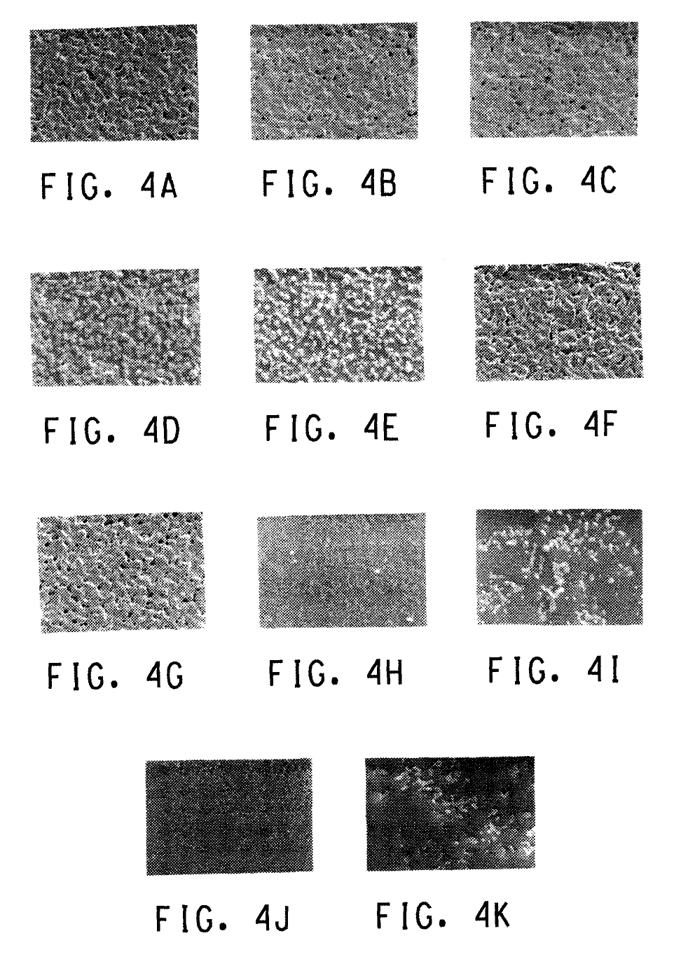

FIG. 4 shows electron micrographs of the surfaces of the rectangular patterns (silver conductors) formed in the center of FIG. 3. In Examples 1 to 7, the diffusion of glass from the insulation layer to the conductor film was prevented on the surface of the silver conductors. On the other hand, in Comparative Examples 1 to 4, the glass component was clearly observed from FIG. 4 to have diffused from the insulation layer onto the surface of the silver conductor circuits.

As is clear from these experimental results, use of the insulation paste for a metal core substrate of the present invention enables the formation of reliable circuits on an insulation layer that have solderability of the silver conductor circuit and are free of positional shifts in the silver conductor circuits, while also lowering the contact resistance between conductor and solder.

What is claimed:

1. A method for fabricating an electronic device comprising steps of:
(a) printing, onto a metal core substrate, an insulation paste comprising (a) a glass powder wherein the glass powder has a softening point of 370 to 560° C., (b) an organic solvent, and (c) a glass diffusion inhibitor selected from the group consisting of alumina (Al₂O₃) powder, titania (TiO₂) powder and mixtures thereof wherein the glass diffusion inhibitor is 12 wt % to 30 wt % based on total weight of the glass powder and the glass diffusion inhibitor;
(b) firing the insulation paste at lower than 650° C. to form an insulating layer;
(c) printing a conductive paste on the insulating layer; and
(d) firing the conductive paste to form an electronic circuit.

2. A method for fabricating an electronic device according to claim 1, wherein mean particle diameter of the glass diffusion inhibitor is 0.1 to 5 μm.

3. A method for fabricating an electronic device according to claim 1, wherein the metal core substrate is selected from the group consisting Cu, Al, Fe, Ni, FeNi and mixture thereof.

4. A method for fabricating an electronic device according to claim 1, further comprising, after step (b),
printing a second insulation paste onto the insulating layer; and
firing the second insulation paste.

5. An electronic device fabricated by the method of claim 1.
